(19) United States
(12) Patent Application Publication
(10) Pub. No.: US 2021/0218224 A1
(43) Pub. Date: Jul. 15, 2021

(54) PULSED LASER LIGHT SOURCE FOR PRODUCING EXCITATION LIGHT IN AN INTEGRATED SYSTEM

(71) Applicant: Quantum-Si Incorporated, Guilford, CT (US)

(72) Inventors: Matthew DYER, Heber City, UT (US); Jonathan M. Rothberg, Guilford, CT (US); Brian Reed, Madison, CT (US); Todd Rearick, Cheshire, CT (US); Gerard Schmid, Guilford, CT (US); Faisal R. Ahmad, Guilford, CT (US); Michael Bellos, Lebanon, CT (US); Benjamin Cipriany, Branford, CT (US); Kyle Preston, Guilford, CT (US); Ali Kabiri, Guilford, CT (US)

(73) Assignee: Quantum-Si Incorporated, Guilford, CT (US)

(21) Appl. No.: 17/149,400

(22) Filed: Jan. 14, 2021

Related U.S. Application Data
(60) Provisional application No. 62/961,127, filed on Jan. 14, 2020.

(51) Int. Cl. H01S 5/042; H01S 5/026; G01N 21/64

(52) U.S. Cl. CPC H01S 5/0428; G01N 21/6486; H01S 5/0268; H01S 5/0427

(57) ABSTRACT

Disclosed herein are aspects of a pulsed laser light source for producing excitation light in an integrated bioanalytical system. In some embodiments, the light source comprises one or more laser diodes that produces pulsed light signals synchronized with a common clock source for excitation of samples within reaction chambers on at least one chip. The light source may be used to provide excitation for a system with a large sensor array with reduced cost, size and electrical power requirements.

### CROSS-REFERENCE TO RELATED APPLICATIONS

This application claims priority to U.S. provisional application No. 62/961,127, filed Jan. 14, 2020 and titled “PULSED LASER LIGHT SOURCE FOR PRODUCING EXCITATION LIGHT IN AN INTEGRATED SYSTEM,” which is incorporated by reference in its entirety.

### FIELD

The present application generally relates to pulsed laser light sources, and in particular to pulsed laser light sources that may be used in a bioanalytical application.

### BACKGROUND

Optical pulses are useful in various areas of research and development as well as commercial applications. For example, optical pulses may be useful for time-domain spectroscopy, optical ranging, time-domain imaging (TDI), optical coherence tomography (OCT), fluorescent lifetime imaging (FLI), and lifetime-resolved fluorescent detection for genetic sequencing.

One application of optical pulses is in the analysis of biological or chemical samples. Such application may involve tagging samples with luminescent markers that emit light of a particular wavelength, illuminating with a light source the tagged samples, and detecting the luminescent light with a photodetector. Such techniques may involve laser light sources and systems to illuminate the tagged samples as well as complex detection optics and electronics to collect the luminescence from the tagged samples.

### SUMMARY OF THE DISCLOSURE

In some embodiments, a system is disclosed. The system comprises an integrated photonic device comprising a plurality of sample wells; a light source comprising at least one laser diode and configured to produce one or more pulsed light signal for exciting a plurality of samples within the plurality of sample wells; and a driver circuit coupled to the light source and configured to receive a clock signal and to control a timing of the one or more pulsed light signal based on the clock signal.

In some embodiments, a system is disclosed. The system comprises a chip comprising a plurality of sample wells and at least one waveguide; at least one laser diode configured to produce one or more pulsed light signal for exciting samples within the plurality of sample wells of the one or more chips via a corresponding waveguide of the at least one waveguide; and a driver circuit configured to receive a clock signal and to synchronize a timing of the produced one or more pulsed light signal based on the clock signal.

In some embodiments, a method of operating a system is disclosed. The system comprises a chip, at least one laser diode and a driver circuit. The chip has a plurality of sample wells. The method comprises receiving a clock signal at the driver circuit; based on the received clock signal, generating one or more drive signals with the driver circuit; producing one or more pulsed light signal with the at least one laser diode based on the one or more drive signals; and exciting a plurality of samples within the plurality of sample wells with the one or more pulsed light signal.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in all the figures in which they appear. In the drawings:

FIG. 1 is a schematic block diagram that illustrates an example of a system 100 with a light source having one or more laser diodes, in accordance with some embodiments;

FIG. 2 is cross-sectional schematic of the integrated device 101 of FIG. 1;

FIG. 3A is a schematic diagram that illustrates an example of optical coupling within a system, in accordance with some embodiments;

FIG. 3B is a schematic top view diagram of the system shown in FIG. 3A, in accordance with some embodiments;

FIG. 4 is a schematic top view diagram of a system that is a variation of the system shown in FIG. 3A, in accordance with some embodiments;

FIG. 5 is a schematic diagram that illustrates an example of optical coupling of multiple laser diodes using separate optical paths and integrated mode converters, in accordance with some embodiments;

FIG. 6 is a schematic block diagram that illustrates an example of a system that uses optical coupling with optical fibers, in accordance with some embodiments;

FIG. 7A is a schematic top view diagram illustrating an example of illuminating an integrated device at multiple inputs, in accordance with some embodiments;

FIG. 7B shows a group of timing diagrams for pulse signals produced by the light sources and waveguides of FIG. 7A to reduce signal cross-talk, in accordance with some embodiments.

### DETAILED DESCRIPTION

Some bioanalytical systems include an integrated device for performing luminescence assays, and a light source to provide excitation of samples analyzed in the integrated device. Aspects of the present application are directed to a pulsed laser source that comprises laser diodes for use in a bioanalytical application for excitation of luminescence assays.

Some aspects of the present application relate to integrated devices, instruments and related systems capable of analyzing samples in parallel, including identification of single molecules and nucleic acid sequencing. Such an instrument may be compact, easy to carry, and easy to operate, allowing a physician or other provider to readily use the instrument and transport the instrument to a desired location where care may be needed. Analysis of a sample may include labeling the sample with one or more fluorescent markers, which may be used to detect the sample and/or identify single molecules of the sample (e.g., individual nucleotide identification as part of nucleic acid sequencing). A fluorescent marker may become excited in response to illuminating the fluorescent marker with excitation light (e.g., light having a characteristic wavelength that may excite the fluorescent marker to an excited state) and, if the fluorescent marker becomes excited, emit emission light (e.g., light having a characteristic wavelength emitted by the fluorescent marker by returning to a ground state from an excited state). Detection of the emission light may allow for identification of the fluorescent marker, and thus, the sample or a molecule of the sample labeled by the fluorescent marker. According to some embodiments, the instrument may be capable of massively-parallel sample analyses and may be configured to handle tens of thousands of samples or more simultaneously.

The inventors have recognized and appreciated that an integrated device, having sample wells configured to receive a sample and integrated optics formed on the integrated device, and an instrument configured to interface with the integrated device may be used to achieve analysis of this number of samples. The instrument may include one or more excitation light sources, and the integrated device may interface with the instrument such that the excitation light is delivered to the sample wells using integrated optical components (e.g., waveguides, optical couplers, optical splitters) formed as part of the integrated device. The optical components may improve the uniformity of illumination across the sample wells of the integrated device and may reduce a large number of external optical components that might otherwise be needed. Furthermore, the inventors have recognized and appreciated that integrating photodetectors on the integrated device may improve detection efficiency of fluorescent emissions from the sample wells and reduce the number of light-collection components that might otherwise be needed.

One illumination solution is a mode-locked laser module, such as those described in U.S. Pat. No. 10,283,928, issued May 7, 2019, titled “COMPACT MODE-LOCKED LASER MODULE,” which is incorporated by reference herein in its entirety. While a mode-locked laser may provide a high-power narrow pulse of <100 ps full-width-half-maximum (FWHM), such a laser module may have high cost, large size, and high electric power consumption. Disclosed herein are embodiments of a bioanalytical system having a laser diode-based pulsed laser source that can provide excitation for the system with reduced cost, size and electrical power requirements.

In one aspect, one or more laser diodes may be used to illuminate a sensor array while using low amount of optical power. The inventors have appreciated and recognized that with continued improvements in sensor sensitivity as well as optical collection efficiency of photonic structures, the amount of laser power that is required to illuminate large sensor arrays in an integrated device can be greatly reduced.

In another aspect, a laser diode may provide an adjustable pulse width, and the ability to reduce peak intensity to extend the lifetime of components in the system for example by reducing photoinduced damage to organic molecules used in the assays, and improving stability of waveguides at high optical powers. The inventors have appreciated and recognized that the requirement for a light source to produce a very narrow pulse of <100 ps FWHM may be relaxed depending on the pixel operation and optical rejection configuration. In a laser diode, relaxing the pulse width requirement may also allow the extraction of a higher amount of optical power.

Some aspects are directed to a bioanalytical system that includes an integrated device, which may be a sensor chip, that is illuminated by a light source having a single or a plurality of laser diodes. The laser diodes are driven by a driver circuit in the system to produce pulsed laser light signals for excitation of samples within reaction chambers or sample wells on the integrated device.

In some embodiments, the timings of the generated pulsed laser light signals are synchronized with timing of a single clock signal from a clock source. In embodiments with a plurality of laser diodes, light signals from each laser diode may be coupled to a different location on the chip, and are synchronized with a single clock signal such that excitation at multiple locations on the chip may be synchronized with the timing of the detection operation on the chip. In some embodiments, timing of pulsed light signal from each laser diode may be adjustable, for example by independently delaying the single clock signal by a predetermined amount. Independent adjustment of timing delay to individual laser diodes may be used to reduce or eliminate skew from a single clock due for example to variations within optical paths coupling each laser diode to the chip.

Some aspects are directed to a compact system that is capable of analyzing biological or chemical samples in parallel, including identification of single molecules and nucleic acid sequencing. The system may include an integrated device and an instrument configured to interface with the integrated device. The instrument may include one or more excitation light sources, and the integrated device may interface with the instrument such that the excitation light is delivered to the sample wells using integrated optical components (e.g., waveguides, optical couplers, optical splitters) formed as part of the integrated device. The integrated device may include an array of pixels, where each pixel includes a sample well and at least one photodetector. A surface of the integrated device may have a plurality of sample wells, where a sample well is configured to receive a sample from a sample placed on the surface of the integrated device. A sample may contain multiple samples, and in some embodiments, different types of samples. The plurality of sample wells may have a suitable size and shape such that at least a portion of the sample wells receive one sample from a sample. In some embodiments, the number of samples within a sample well may be distributed among the sample wells such that some sample wells contain one sample with others contain zero, two or more samples.

In some embodiments, a sample may be a biological and/or chemical sample for nucleic acid (e.g. DNA, RNA) sequencing or protein sequencing. For example, a sample may contain multiple single-stranded DNA templates, and individual sample wells on a surface of an integrated device may be sized and shaped to receive a sequencing template. Sequencing templates may be distributed among the sample wells of the integrated device such that at least a portion of the sample wells of the integrated device contain a sequencing template. The sample may also contain labeled nucleotides which then enter in the sample well and may allow for identification of a nucleotide as it is incorporated into a strand of DNA complementary to the single-stranded DNA template in the sample well. In such an example, the “sample” may refer to both the sequencing template and the labeled nucleotides currently being incorporated by a polymerase. In some embodiments, the sample may contain sequencing templates and labeled nucleotides may be subsequently introduced to a sample well as nucleotides are incorporated into a complementary strand within the sample well. In this manner, timing of incorporation of nucleotides may be controlled by when labeled nucleotides are introduced to the sample wells of an integrated device.

Excitation light is provided from an excitation source located separate from the pixel array of the integrated device. The excitation light is directed at least in part by elements of the integrated device towards one or more pixels to illuminate an illumination region within the sample well. A marker may then emit emission light when located within the illumination region and in response to being illuminated by excitation light. In some embodiments, one or more excitation sources are part of the instrument of the system where components of the instrument and the integrated device are configured to direct the excitation light towards one or more pixels.

Emission light emitted by a sample may then be detected by one or more photodetectors within a pixel of the integrated device. Characteristics of the detected emission light may provide an indication for identifying the marker associated with the emission light. Such characteristics may include any suitable type of characteristic, including an arrival time of photons detected by a photodetector, an amount of photons accumulated over time by a photodetector, a distribution of photons across two or more photodetectors, a wavelength value, intensity, signal pulse width, lifetime, discrimination, or any combination thereof. In some embodiments, a photodetector may have a configuration that allows for the detection of one or more timing characteristics associated with a sample's emission light (e.g., fluorescence lifetime). The photodetector may detect a distribution of photon arrival times after a pulse of excitation light propagates through the integrated device, and the distribution of arrival times may provide an indication of a timing characteristic of the sample's emission light (e.g., a proxy for fluorescence lifetime). In some embodiments, the one or more photodetectors provide an indication of the probability of emission light emitted by the marker (e.g., fluorescence intensity). In some embodiments, a plurality of photodetectors may be sized and arranged to capture a spatial distribution of the emission light. Output signals from the one or more photodetectors may then be used to distinguish a marker from among a plurality of markers, where the plurality of markers may be used to identify a sample within the sample. In some embodiments, a sample may be excited by multiple excitation energies, and emission light and/or timing characteristics of the emission light emitted by the sample in response to the multiple excitation energies may distinguish a marker from a plurality of markers.

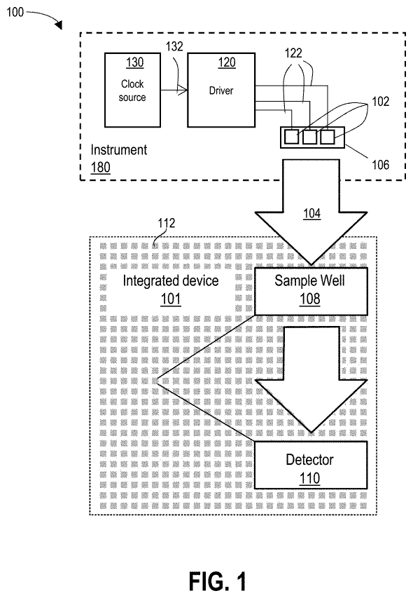

FIG. 1 is a schematic block diagram that illustrates an example of a system 100 with a light source having one or more laser diodes, in accordance with some embodiments. The system 100 comprises an integrated device 101 that interfaces with an instrument 180. Instrument 180 may include a light source 106 coupled to a driver circuit 120 which is coupled to a clock source 130. In some embodiments, light source 106 may be configured to generate and direct one or more pulsed light signal 104 to the integrated device. In some embodiments, an excitation light source may be external to both instrument 180 and integrated device 101, and instrument 180 may be configured to receive excitation light from the excitation source and direct excitation light to the integrated device. The integrated device may interface with the instrument using any suitable socket for receiving the integrated device and holding it in precise optical alignment with the excitation source.

The integrated device 101 has a plurality of pixels 112, where at least a portion of pixels may perform independent analysis of a sample. Such pixels 112 may be referred to as “passive source pixels” since a pixel receives excitation light from light source 106 separate from the pixel, where excitation light from the source excites some or all of the pixels 112.

A pixel 112 has a sample well 108, also referred to as a reaction chamber, that is configured to receive a sample and a photodetector 110 for detecting emission light emitted by the sample in response to illuminating the sample with excitation light provided by the light source 106. In some embodiments, sample well 108 may retain the sample in proximity to a surface of integrated device 101, which may ease delivery of excitation light to the sample and detection of emission light from the sample.

Optical elements for coupling excitation light from light source 106 to integrated device 101 and guiding pulsed light signals 104 to the sample well 108 may be located both on integrated device 101 and external to the integrated device 101. Source-to-well optical elements may comprise one or more grating couplers located on integrated device 101 to couple excitation light to the integrated device and waveguides to deliver excitation light from instrument 104 to sample wells in pixels 112. One or more optical splitter elements may be positioned between a grating coupler and the waveguides. The optical splitter may couple excitation light from the grating coupler and deliver excitation light to at least one of the waveguides. In some embodiments, the optical splitter may have a configuration that allows for delivery of excitation light to be substantially uniform across all the waveguides such that each of the waveguides receives a substantially similar amount of excitation light. Such embodiments may improve performance of the integrated device by improving the uniformity of excitation light received by sample wells of the integrated device. Some examples of source-to-well optical elements are described in U.S. patent application Ser. No. 16/733,296, filed on Jan. 3, 2020, titled “OPTICAL WAVEGUIDES AND COUPLERS FOR DELIVERING LIGHT TO AN ARRAY OF PHOTONIC ELEMENTS,” the entirety of which is herein incorporated by reference herein in its entirety. Examples of suitable components, for coupling excitation light to a sample well and/or directing emission light to a photodetector, to include in an integrated device are described in U.S. patent application Ser. No. 14/821,688, filed Aug. 7, 2015, titled “INTEGRATED DEVICE FOR PROBING, DETECTING AND ANALYZING MOLECULES,” and U.S. patent application Ser. No. 14/543,865, filed Nov. 17, 2014, titled “INTEGRATED DEVICE WITH EXTERNAL LIGHT SOURCE FOR PROBING, DETECTING, AND ANALYZING MOLECULES,” each of which is incorporated herein by reference in its entirety.

Sample well 108, a portion of the excitation source-to-well optics, and the sample well-to-photodetector optics are located on integrated device 101, sometimes also referred to as a chip or sensor chip. Light source 106 and a portion of the source-to-well components are located off the chip 101. In some embodiments, a single component may play a role in both coupling excitation light to sample well 108 and delivering emission light from sample well 108 to photodetector 110. Pixel 112 is associated with its own individual sample well 108 and at least one photodetector 110. The plurality of pixels of integrated device 101 may be arranged to have any suitable shape, size, and/or dimensions. Integrated device 101 may have any suitable number of pixels or sample wells. In some embodiments, integrated device 101 may have an array of 1 million, 8 million, 32 million, between 1 and 10 million, between 10 and 50 million, or any suitable number of sample wells excited by light signals 104 generated by light source 106.

In some embodiments, the pixels may be arranged in an array of 512 pixels by 512 pixels. Integrated device 101 may interface with instrument 180 in any suitable manner. In some embodiments, instrument 180 may have an interface that detachably couples to integrated device 101 such that a user may attach integrated device 101 to instrument 180 for use of integrated device 101 to analyze a sample and remove integrated device 101 from instrument 180 to allow for another integrated device to be attached. The interface of instrument 180 may position integrated device 101 to couple with circuitry of instrument 180 to allow for readout signals from one or more photodetectors to be transmitted to instrument 180. Integrated device 101 and instrument 180 may include multi-channel, high-speed communication links for handling data associated with large pixel arrays (e.g., more than 10,000 pixels).

In FIG. 1, light source 106 has three laser diodes 102. It should be appreciated that while three laser diodes are shown, they are only an illustrative example and aspects of the present application are not so limited and light source 106 may be one laser diode, 16 laser diodes, 32 laser diodes, between 1 and 10 laser diodes, between 10 and 50 laser diodes, or any suitable number of laser diodes. Each laser diode 102 is independently driven by a drive signal 122 generated by the driver circuit 120 to produce a pulsed laser light signal 104. In some embodiments, laser diode 102 is operated at a low output power to reduce photoinduced damage to organic molecules used in the sample wells, and to improve stability of waveguides at high optical powers. A total output optical power for laser diodes 102 in light source 106 may be 5 mW, 10 mW, 25 mW, 100 mW, between 5 and 100 mW, between 5 and 200 mW, or any suitable range of output power levels. In some embodiments, integrated device 101 may have an array of at least 1 million sample wells excited by light source 106 operated at an optical power of between 5 and 100 mW. In some embodiments, integrated device 101 may have an array of at least 8 million sample wells excited by light source 106 operated at an optical power of between 10 and 100 mW. In some embodiments, integrated device 101 may have an array of at least 32 million sample wells excited by light source 106 operated at an optical power of between 10 and 100 mW.

Laser diode 102 may be implemented by any suitable laser diode known to a skilled person. In some embodiments, laser diode 102 may be a microdisk laser. Laser diode 102 may be operated in a gain-switched mode to produce short pulses of light. In some embodiments, light pulses generated by laser diode 102 may have a FWHM of at least 100 ps, at least 1000 ps, between 100 ps and 1000 ps, more than 1 ns or any suitable width. In some embodiments, light pulses generated by laser diode 102 may have a wavelength of between 488 and 525 nm, between 640 and 670 nm, or any suitable wavelength. In some embodiments, laser diode 102 may be operated in an amplitude modulation mode, and is modulated by an input electrical signal that can be a sinusoidal signal, which is different in nature from electrical signal used to operate a gain-switched laser diode. In some embodiments where pulse widths are more than 1 ns, other forms of laser pulsing may be used such as current modulation or a slow or sinusoidal drive.

Laser diode 102 may be a single mode emitter, and may in one example be an emitter with output power at green wavelengths at between 5 and 25 mW. In some embodiments, light source 106 may comprise an array of laser diodes 102 arranged in a laser diode bar. Laser diodes may be monolithically integrated in a bar, although discrete and separate laser diodes may also be used and arranged to form an array. Any suitable number of laser diodes or spatial arrangement may be provided in a laser diode bar, and laser diodes may be tightly packed or spaced from each other as aspects of the present application are not so limited. An array of diode emitters may be driven together with parallel outputs. In one example, the diodes are arranged as a monolithic array of single mode emitters. In some embodiments, laser diode 102 may provide multimode output.

Still referring to FIG. 1, driver circuit 120 receives a master clock signal 132 from clock source 130, and generates drive signals 122 to synchronize generation of the pulsed light signal 104 by laser diodes 102 in the light source 106. In some embodiments, timings of each drive signal may be adjustable, for example by one or more programmable delay lines or any suitable delay circuits within the driver circuit 120 that can generate a corresponding delayed timing signal that is a delayed version of the master clock signal 132 and used to set the timing of each drive signal 122. The amount of programmable delays applied to each drive signal may be selected to synchronize excitation of samples in the chip 101 with pulsed light signals produced by different laser diodes 102 within light source 106. For example, the delays may be adjusted to compensate for the variance of propagation delays in optical paths for different laser diodes to excite sample wells at the same timing on the chip to reduce or eliminate skew across the array of laser diodes. In some embodiments, delays applied to each drive signal may be selected such that the excitation at sample wells on the chip by different laser diodes is synchronized with a timing of time-domain sensing operations on the chip. In some embodiments, the amount of programmable delays may be determined during a calibration procedure that iteratively adjusts one or more delay amounts in the driver circuit until a timing relationship such as a measured amount of skew is within a predefined threshold.

Driver circuit 120 and clock source 130 may be implemented in any suitable ways. In some embodiments, driver circuit 120 may comprise an integrated circuit disposed in a semiconductor substrate. In some embodiments, driver circuit 120 may comprise one or more printed circuit boards (PCBs). In some embodiments, driver circuit 120 may comprise a plurality of driver units corresponding to each laser diode within the light source. Driver circuit 120 may copy the received master clock signal 132, apply a programmable delay, and generate a delayed clock signal as timing for each of the plurality of driver units. In some embodiments, the clock source 130 and driver circuit 120 may be part of an instrument that interface with the integrated device for analyzing readout signals from one or more photodetectors in the pixels on the chip, and the clock signal 132 may be synchronized with a clock within such an instrument for analysis of the readout signals. For example, a signal derived from sensing the optical pulses can be used to generate an electronic clock signal that can be used to synchronize instrument electronics (e.g., data acquisition cycles) with the timing of optical pulses produced by the light source. Examples of an instrument are described in U.S. patent application Ser. No. 16/733,296, filed on Jan. 3, 2020, titled “OPTICAL WAVEGUIDES AND COUPLERS FOR DELIVERING LIGHT TO AN ARRAY OF PHOTONIC ELEMENTS,” the entirety of which is herein incorporated by reference herein in its entirety. In other embodiments, driver circuit 120 and/or clock source 130 may also be provided independently from such an instrument.

In some embodiments, excitation light can be steered through just a portion of a laser diode array at a time, which would reduce the electric power consumption of a system. In such embodiments, driver circuit 120 may independently activate/deactivate a portion of laser diodes within light source 106 for excitation of a pixel. The inventors have recognized and appreciated that at least some power consumption are attributed to switching of logic gates within the chip, which may be reduced by reducing the frequency of excitation light pulses seen by a pixel on the chip. In one non-limiting example, instead of driving an entire array of laser diodes are normally driven with 10 mW of total output power, the power can be concentrated on half the array for half time, and vice versa. This reduces the toggle frequency of logic gates in the pixel by a factor of two and as a result every pixel receives half the number of light pulses, but have twice the power and the same average power. It should be appreciated that other variations of differentially driving portions of a laser diode array may also be used.

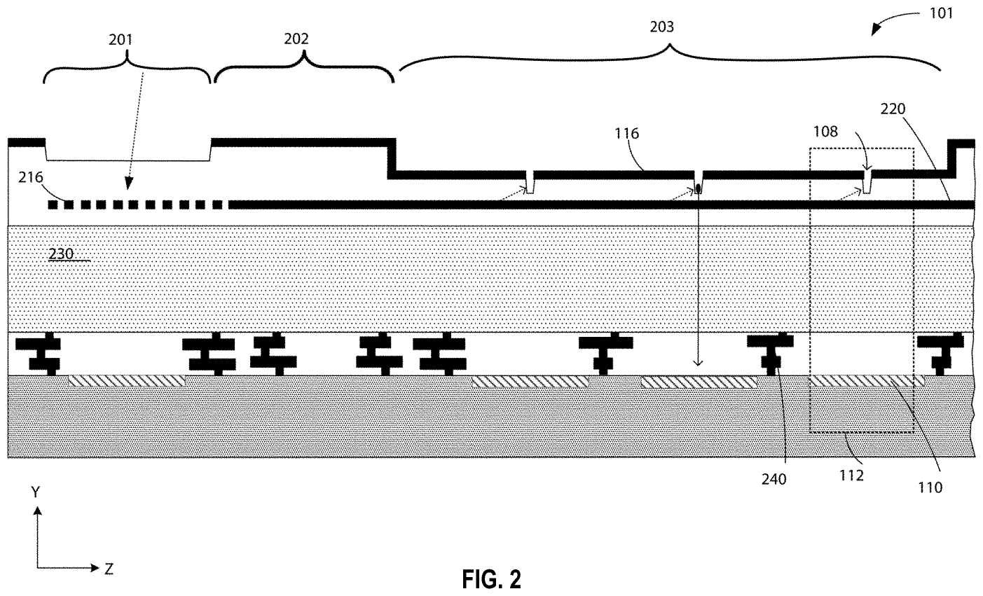

A cross-sectional schematic of integrated device 101 illustrating a row of pixels 112 is shown in FIG. 2. Integrated device 101 may include coupling region 201, routing region 202, and pixel region 203. Pixel region 203 may include a plurality of pixels 112 having sample wells 108 positioned on a surface at a location separate from coupling region 201, which is where excitation light (shown as the dashed arrow) couples to integrated device 101. Sample wells 108 may be formed through metal layer(s) 116. One pixel 112, illustrated by the dotted rectangle, is a region of integrated device 101 that includes a sample well 108 and photodetector region having one or more photodetectors 110.

FIG. 2 illustrates the path of excitation (shown in dashed lines) by coupling a beam of excitation light to coupling region 201 and to sample wells 108. The row of sample wells 108 shown in FIG. 2 may be positioned to optically couple with waveguide 220. Excitation light may illuminate a sample located within a sample well. The sample may reach an excited state in response to being illuminated by the excitation light. When a sample is in an excited state, the sample may emit emission light, which may be detected by one or more photodetectors associated with the sample well. FIG. 2 schematically illustrates the path of emission light (shown as the solid line) from a sample well 108 to photodetector(s) 110 of pixel 112. The photodetector(s) 110 of pixel 112 may be configured and positioned to detect emission light from sample well 108. Examples of suitable photodetectors are described in U.S. patent application Ser. No. 14/821,656, filed Aug. 7, 2015, titled “INTEGRATED DEVICE FOR TEMPORAL BINNING OF RECEIVED PHOTONS,” which is incorporated by reference herein in its entirety. Additional examples of suitable photodetectors are described in U.S. patent application Ser. No. 15/852,571, filed Dec. 22, 2017, titled “INTEGRATED PHOTODETECTOR WITH DIRECT BINNING PIXEL,” which is incorporated herein by reference in its entirety. For an individual pixel 112, a sample well 108 and its respective photodetector(s) 110 may be aligned along a common axis (along the y-direction shown in FIG. 2). In this manner, the photodetector(s) may overlap with the sample well within a pixel 112.

The directionality of the emission light from a sample well 108 may depend on the positioning of the sample in the sample well 108 relative to metal layer(s) 116 because metal layer(s) 116 may act to reflect emission light. In this manner, a distance between metal layer(s) 116 and a fluorescent marker positioned in a sample well 108 may impact the efficiency of photodetector(s) 110, that are in the same pixel as the sample well, to detect the light emitted by the fluorescent marker. The distance between metal layer(s) 116 and the bottom surface of a sample well 106, which is proximate to where a sample may be positioned during operation, may be in the range of 100 nm to 500 nm, or any value or range of values in that range. In some embodiments the distance between metal layer(s) 116 and the bottom surface of a sample well 108 is approximately 300 nm.

The distance between the sample and the photodetector(s) may also impact efficiency in detecting emission light. By decreasing the distance light has to travel between the sample and the photodetector(s), detection efficiency of emission light may be improved. In addition, smaller distances between the sample and the photodetector(s) may allow for pixels that occupy a smaller area footprint of the integrated device, which can allow for a higher number of pixels to be included in the integrated device. The distance between the bottom surface of a sample well 108 and photodetector(s) may be in the range of 1 μm to 15 μm, or any value or range of values in that range.

Photonic structure(s) 230 may be positioned between sample wells 108 and photodetectors 110 and configured to reduce or prevent excitation light from reaching photodetectors 110, which may otherwise contribute to signal noise in detecting emission light. As shown in FIG. 2, the one or more photonic structures 230 may be positioned between waveguide 220 and photodetectors 110. Photonic structure(s) 230 may include one or more optical rejection photonic structures including a spectral filter, a polarization filter, and a spatial filter. Photonic structure(s) 230 may be positioned to align with individual sample wells 108 and their respective photodetector(s) 110 along a common axis. Metal layers 240, which may act as a circuitry for integrated device 101, may also act as a spatial filter, in accordance with some embodiments. In such embodiments, one or more metal layers 240 may be positioned to block some or all excitation light from reaching photodetector(s) 110.

Coupling region 201 may include one or more optical components configured to couple excitation light from an external excitation source. Coupling region 201 may include grating coupler 216 positioned to receive some or all of a beam of excitation light. Examples of suitable grating couplers are described in U.S. patent application Ser. No. 15/844,403, filed Dec. 15, 2017, titled “OPTICAL COUPLER AND WAVEGUIDE SYSTEM,” which is incorporated by reference herein in its entirety. Grating coupler 216 may couple excitation light to waveguide 220, which may be configured to propagate excitation light to the proximity of one or more sample wells 108. Alternatively, coupling region 201 may comprise other well-known structures for coupling light into a waveguide.

Components located off of the integrated device may be used to position and align the excitation source 106 to the integrated device. Such components may include optical components including lenses, mirrors, prisms, windows, apertures, attenuators, and/or optical fibers. Additional mechanical components may be included in the instrument to allow for control of one or more alignment components. Such mechanical components may include actuators, stepper motors, and/or knobs. Examples of suitable excitation sources and alignment mechanisms are described in U.S. patent application Ser. No. 15/161,088, filed May 20, 2016, titled “PULSED LASER AND SYSTEM,” which is incorporated by reference herein in its entirety. Another example of a beam-steering module is described in U.S. patent application Ser. No. 15/842,720, filed Dec. 14, 2017, titled “COMPACT BEAM SHAPING AND STEERING ASSEMBLY,” which is incorporated herein by reference in its entirety.

A sample to be analyzed may be introduced into sample well 108 of pixel 112. The sample may be a biological sample or any other suitable sample, such as a chemical sample. The sample may include multiple molecules and the sample well may be configured to isolate a single molecule. In some instances, the dimensions of the sample well may act to confine a single molecule within the sample well, allowing measurements to be performed on the single molecule. Excitation light may be delivered into the sample well 108, so as to excite the sample or at least one fluorescent marker attached to the sample or otherwise associated with the sample while it is within an illumination area within the sample well 108.

In operation, parallel analyses of samples within the sample wells are carried out by exciting some or all of the samples within the wells using excitation light and detecting signals from sample emission with the photodetectors. Emission light from a sample may be detected by a corresponding photodetector and converted to at least one electrical signal. The electrical signals may be transmitted along conducting lines (e.g., metal layers 240) in the circuitry of the integrated device, which may be connected to an instrument interfaced with the integrated device. The electrical signals may be subsequently processed and/or analyzed. Processing or analyzing of electrical signals may occur on a suitable computing device either located on or off the instrument.

Instrument 180 may include a user interface for controlling operation of instrument 180 and/or integrated device 101. The user interface may be configured to allow a user to input information into the instrument, such as commands and/or settings used to control the functioning of the instrument. In some embodiments, the user interface may include buttons, switches, dials, and a microphone for voice commands. The user interface may allow a user to receive feedback on the performance of the instrument and/or integrated device, such as proper alignment and/or information obtained by readout signals from the photodetectors on the integrated device. In some embodiments, the user interface may provide feedback using a speaker to provide audible feedback. In some embodiments, the user interface may include indicator lights and/or a display screen for providing visual feedback to a user.

In some embodiments, instrument 180 may include a computer interface configured to connect with a computing device. Computer interface may be a USB interface, a FireWire interface, or any other suitable computer interface. Computing device may be any general purpose computer, such as a laptop or desktop computer. In some embodiments, computing device may be a server (e.g., cloud-based server) accessible over a wireless network via a suitable computer interface. The computer interface may facilitate communication of information between instrument 180 and the computing device. Input information for controlling and/or configuring the instrument 180 may be provided to the computing device and transmitted to instrument 180 via the computer interface. Output information generated by instrument 180 may be received by the computing device via the computer interface. Output information may include feedback about performance of instrument 180, performance of integrated device 112, and/or data generated from the readout signals of photodetector 110.

In some embodiments, instrument 180 may include a processing device configured to analyze data received from one or more photodetectors of integrated device 101 and/or transmit control signals to excitation source(s) 106. In some embodiments, the processing device may comprise a general purpose processor, a specially-adapted processor (e.g., a central processing unit (CPU) such as one or more microprocessor or microcontroller cores, a field-programmable gate array (FPGA), an application-specific integrated circuit (ASIC), a custom integrated circuit, a digital signal processor (DSP), or a combination thereof.) In some embodiments, the processing of data from one or more photodetectors may be performed by both a processing device of instrument 180 and an external computing device. In other embodiments, an external computing device may be omitted and processing of data from one or more photodetectors may be performed solely by a processing device of integrated device 101.

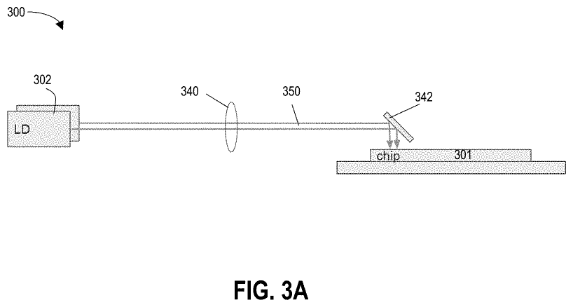

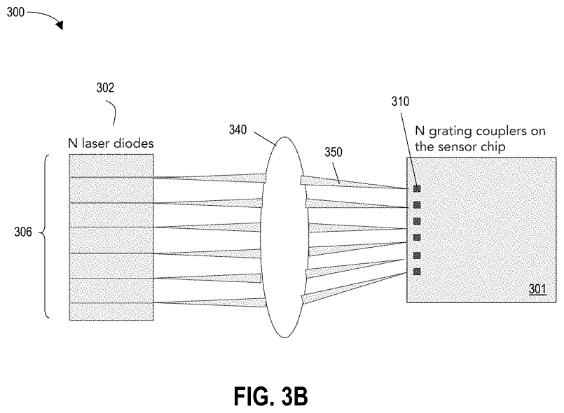

FIG. 3A is a schematic diagram that illustrates an example of optical coupling within a system 300, in accordance with some embodiments. In FIG. 3A, pulsed light signals produced by laser diodes 302 are coupled to a surface of chip 301 by one or more optical path 350. A lens 340 and mirror 342 are disposed in the optical path 350 to align, shape, and direct the pulsed light signals to portions of the chip 301.

FIG. 3B is a schematic top view diagram of the system 300 shown in FIG. 3A, in accordance with some embodiments. FIG. 3B shows that multiple laser diodes 302 are grouped together to form a single bar 206, with generated light signals imaged onto a group of grating couplers 310 disposed on chip 301 via lens 340 and respective optical paths 350. Each of the N laser diodes 302 is thus optically coupled to an individual grating coupler of the N grating couplers 310. Laser diodes 302 can be individually driven and synchronized to a single clock by a driver circuit such as driver circuit 120, while some or all of the laser diodes 302 may also be grouped together and driven in a serial fashion.

While FIGS. 3A and 3B show multiple optical paths sharing the same optical components such as a mirror and a lens, aspects of the present application are not so limited and any suitable number of optical elements may be provided. In some embodiments, optical paths that originate from different laser diodes may have different orientations and lengths to for example illuminate different portions of chip 301. In some embodiments, one or more lens may be used to focus and magnify light signals from the laser diodes to match the pitch and location of corresponding grating couplers on the chip.

In FIG. 3B, grating couplers 310 may be further optically coupled to waveguides and to the sample wells on chip 301. Grating couplers may be any suitable type of couplers, such as but not limited to tapered grating coupler, sliced grating coupler, waveguide tapered couplers, and waveguide evanescent couplers.

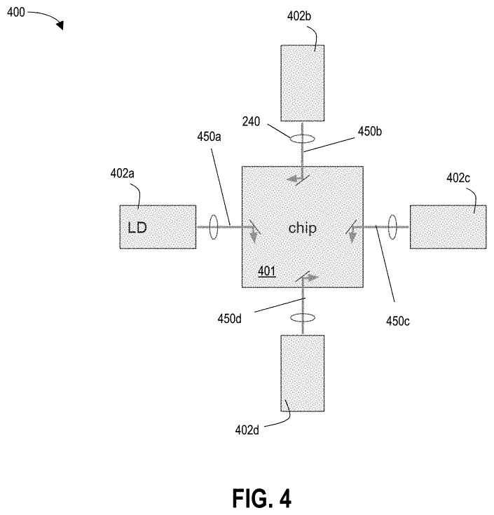

FIG. 4 is a schematic top view diagram of a system 400 that is a variation of the system shown in FIG. 3A, in accordance with some embodiments. In FIG. 4, multiple laser diodes 402a, 402b, 402c, 402d are positioned separate from each other and on different sides of the chip 401. For example, chip 401 is disposed in between laser diodes 402a and 402c, such that optical path 450a from laser diode 402a is about 180 degrees rotated from optical path 450c from laser diode 402c. Optical path 450a from laser diode 402a is about 90 degrees rotated from optical path 450b from laser diode 402b. One advantage of positioning multiple laser diodes separately is that optical paths from the laser diodes can be spaced from each other, which avoids bringing the optical beams close in proximity to each other when the grating couplers on chip 401 are closely packed. As another advantage, positioning laser diodes close to respective sides of chip 401 may reduce the optical path length for transmission of the excitation light, thus reducing delay and waveguide optical losses and increasing system efficiency. For example, light path 450b may be used to excite sample wells located closer to the top side of chip 401 via grating couplers located closer to the top side of chip 401, without requiring long waveguides that route light coupled from locations relatively far away from the top side.

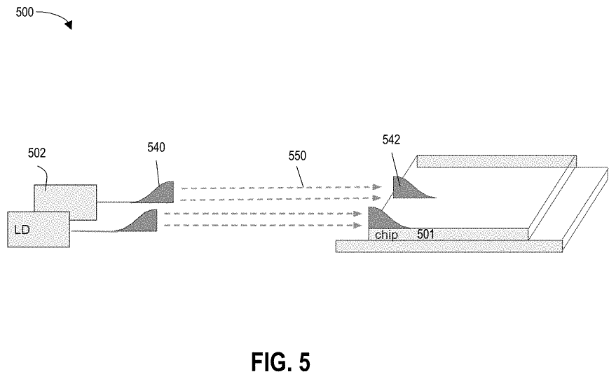

FIG. 5 is a schematic diagram that illustrates an example of optical coupling of multiple laser diodes using separate optical paths and integrated mode converters, in accordance with some embodiments. FIG. 5 shows that light signal generated by each laser diodes 502 is coupled by mode converter 540, optical path 550 and mode converter 542 to chip 501. In some embodiments, separate optical paths 550 are provided for separate laser diodes 520. Mode converters may be micro-optical elements, integrated photonic structures, or any suitable structures, and in some embodiments may relax positioning tolerances required to achieve high coupling efficiency between laser diodes and the chip. System 500 may provide minimized optical intensity at exposed optical interfaces to avoid component failure, and may be implemented using 3D printing methods for monolithic micro/nano-fabrication. According to an aspect, coupling using mode converters may allow passive alignment of laser diodes 502 to chip 501.

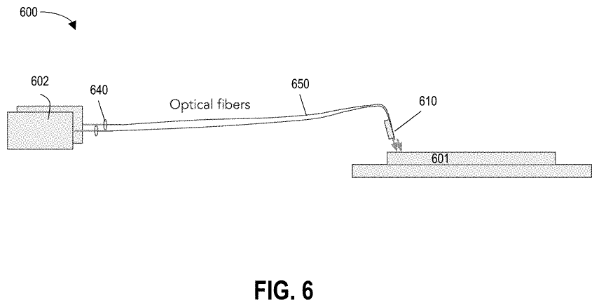

It should be appreciated that while FIGS. 3A, 3B, 4 illustrate optical paths 350 in free space, aspects of the present application are not so limited. FIG. 6 is a schematic block diagram that illustrates an example of a system 600 that uses optical coupling with optical fibers, in accordance with some embodiments. FIG. 6 shows a group of optical fibers 650 coupling laser diodes 602 to chip 601. Each laser diode 602 is coupled into an optical fiber 650, which is coupled to chip 601 via coupler 610.

According to some aspects, the optical fibers 650 may act as a mode filter which outputs a diffraction-limited spot to efficiently couple light signals into a grating coupler on the chip 601. Optionally and additionally, coupling efficiency of the light signal from laser diode 602 into the optical fiber 650 may be enhanced with one or more lenses 640. In some embodiments, the output ends of optical fiber 650 may be arranged into a fiber array positioned close to the chip 601 to couple light from each optical fiber into a corresponding grating coupler. The fiber array may conveniently set the coupling angle for all optical fibers together. In some embodiments, the position and/or angle of the fiber array may be adjusted by a programmable manipulator such as a motor in order to align and stabilize the alignment with respective grating couplers to optimize the coupling efficiency. In some embodiments, coupler 610 may include a pluggable receptacle on the chip 601, and the fiber array may be plugged into the receptacle to help set the position and angle of the fiber array with respect to the grating couplers.

One aspect of the present application is directed to reducing cross-talk between adjacent sensors on the chip. During device scaling, the spacing between adjacent pixels or reaction chambers on an integrated device may be reduced such that more sensors can be packed into a smaller area. In some cases such scaling may result in “cross-talk” of signals between sensors. The inventors have recognized and appreciated that when multiple excitation inputs are provided, cross-talk may be reduced or minimized by offsetting the timing of the excitation between nearby sensors.

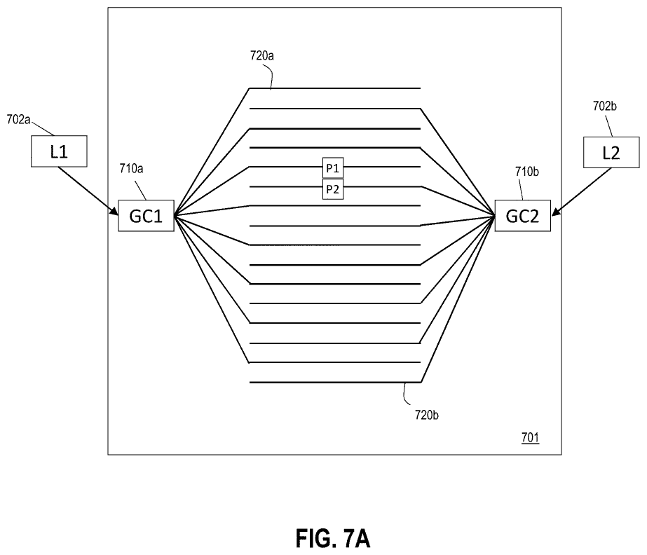

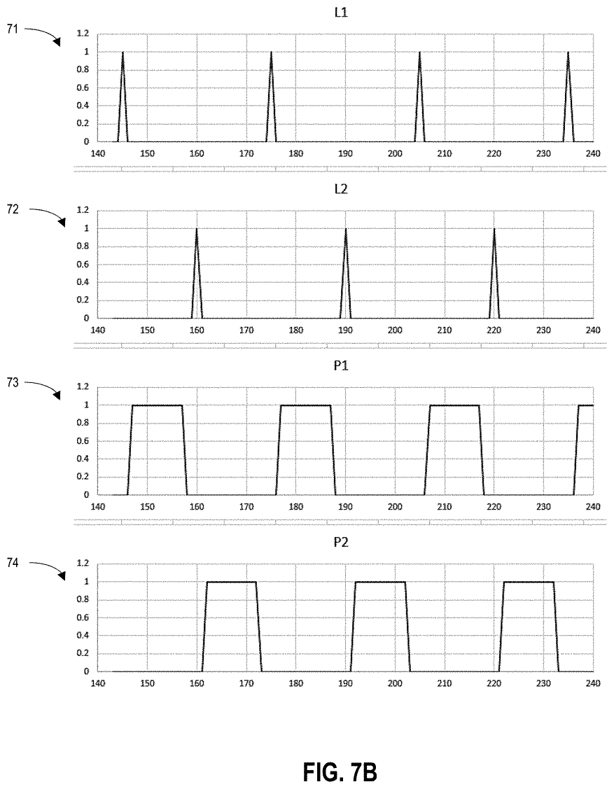

FIG. 7A is a schematic top view diagram illustrating an example of illuminating an integrated device at multiple inputs, in accordance with some embodiments. FIG. 7A shows multiple light sources 702a, 702b each of which couples light signals into respective waveguides 720a, 720b via grating couplers 710a, 710b. Light source 702a includes a laser diode L1, while light source 702b includes a laser diode L2. Pixels P1 and P2 are each coupled to waveguides 720a, 720b, respectively. Cross-talk may occur when pixels P1, P2 are spatially close to one another.

FIG. 7B shows a group of timing diagrams for pulse signals produced by the light sources and waveguides of FIG. 7A to reduce signal cross-talk, in accordance with some embodiments. In FIG. 7B, diagram 71 is a timing diagram for laser pulses produced by L1, diagram 72 is a timing diagram for laser pulses produced by L2, diagram 73 is a timing diagram for collection of sensing signals in P1, and diagram 73 is a timing diagram for collection of sensing signals in P2. As shown in FIG. 7B, the L1, L2 pulses are offset in time, and the P1, P2 collection windows are also offset in time. Without wishing to be bound by a particular theory, the timing configurations may reduce cross-talk at the sensors within pixels P1, P2 because the adjacent sensors are excited at different times that are outside of the collection window. It should be appreciated that the timing diagrams shown in FIG. 7B are by way of example only, and any suitable amount of timing offset may be used in some or all of the collection and excitation timings to reduce cross-talk.

Various aspects of the technology may be used alone, in combination, or in a variety of arrangements not specifically discussed in the embodiments described in the foregoing and is therefore not limited in its application to the details and arrangement of components set forth in the foregoing description or illustrated in the drawings. For example, while in some examples a single chip is illustrated, it should be appreciated that a system may comprise more than one chip, and that a light source in accordance with aspects of the present application may also be used to excite a plurality of chips. Aspects described in one embodiment may be combined in any manner with aspects described in other embodiments.

Also, aspects of the technology may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. A system comprising:
an integrated photonic device comprising a plurality of sample wells;
a light source comprising at least one laser diode and configured to produce one or more pulsed light signals for exciting a plurality of samples within the plurality of sample wells; and
a driver circuit coupled to the light source and configured to receive a clock signal and to control a timing of the one or more pulsed light signals based on the clock signal.

2. The system of claim 1, wherein the at least one laser diode comprises a plurality of laser diodes, and wherein the driver circuit is further configured to generate a plurality of drive signals having timing based on the clock signal to drive respective laser diodes within the plurality of laser diodes with the drive signals.

3. The system of claim 2, wherein the driver circuit is further configured to apply an adjustable delay to timing in some or all of the plurality of drive signals.

4. The system of claim 1, wherein the at least one laser diode is configured to operate in an amplitude modulation mode.

5. The system of claim 1, wherein the integrated photonic device comprises at least one million sample wells and wherein the at least one laser diode is configured to produce the one or more pulsed light signals with an optical power level of less than 100 mW.

6. The system of claim 1, further comprising at least one waveguide configured to optically couple the one or more pulsed light signals to some or all of the plurality of sample wells.

7. The system of claim 6, wherein the integrated photonic device further comprises one or more grating couplers configured to optically couple the one or more pulsed light signals to the at least one waveguide.

8. The system of claim 7, wherein the light source comprises an array of laser diodes, the one or more grating couplers are a plurality of grating couplers, and the system further comprises a plurality of optical paths each coupling a laser diode of the array of laser diodes to a corresponding grating coupler of the plurality of grating couplers.

9. The system of claim 8, wherein the plurality of optical paths comprise a first optical path and a second optical path that form an angle of at least 90 degrees.

10. The system of claim 6, further comprising one or more optical elements configured to optically couple the one or more pulsed light signals to the at least one waveguide, wherein the one or more optical elements comprises a mirror, a lens, an optical fiber or combinations thereof.

11. The system of claim 1, wherein the at least one laser diode comprises a gain-switched laser diode, and wherein the one or more pulsed light signals has a full-width-half-maximum of between 100 and 1000 ps.

12. A system comprising:
a chip comprising a plurality of sample wells and at least one waveguide;
at least one laser diode configured to produce one or more pulsed light signals for exciting samples within the plurality of sample wells of the chip via a corresponding waveguide of the at least one waveguide; and
a driver circuit configured to receive a clock signal and to synchronize a timing of the produced one or more pulsed light signals based on the clock signal.

13. The system of claim 12, wherein the at least one laser diode comprises a plurality of laser diodes, and wherein the driver circuit is further configured to generate a plurality of drive signals having timing based on the clock signal to drive respective laser diodes within the plurality of laser diodes with the drive signals.

14. The system of claim 12, wherein the chip comprises at least one million sample wells and wherein the at least one laser diode is configured to produce the one or more pulsed light signals with an optical power level of less than 100 mW.

15. The system of claim 12, wherein the chip further comprises one or more grating couplers configured to optically couple the one or more pulsed light signals to the at least one waveguide.

16. A method of operating a system comprising a chip, at least one laser diode and a driver circuit, the chip having a plurality of sample wells, the method comprises:
receiving a clock signal at the driver circuit;
based on the received clock signal, generating one or more drive signals with the driver circuit;
producing one or more pulsed light signals with the at least one laser diode based on the one or more drive signals; and
exciting a plurality of samples within the plurality of sample wells with the one or more pulsed light signals.

17. The method of claim 16, wherein the at least one laser diode comprises a plurality of laser diodes, and the method further comprises:
generating a plurality of synchronized pulsed light signals based on the clock signal.

18. The method of claim 17, wherein generating the plurality of synchronized pulsed light signals comprises:
generating, with the driver circuit, a plurality of drive signals each having a timing based on the clock signal; and
driving each laser diode of the plurality of laser diodes with a corresponding drive signal.

19. The method of claim 18, wherein generating the plurality of drive signals comprises:
delaying the clock signal to produce a plurality of delayed timing signals each having a programmable delay;
setting the timing of each of the drive signal based on a corresponding delayed timing signal, wherein
the programmable delay for each drive signal are selected such that the plurality of synchronized pulsed light signals excite the plurality of samples in the chip with a predefined timing relationship.

20. The method of claim 16, wherein the chip has at least one million sample wells and wherein producing one or more pulsed light signals comprises operating the at least one laser diode to produce a pulsed light signal with an optical power level of less than 100 mW.
